(19) United States
(12) Patent Application Publication
(10) Pub. No.: US 2020/0211968 A1
(43) Pub. Date: Jul. 2, 2020

(54) SEMICONDUCTOR STRUCTURE AND MANUFACTURING METHOD THEREOF

(71) Applicant: NANYA TECHNOLOGY CORPORATION, New Taipei City (TW)

(72) Inventor: TSANG-PO YANG, NEW TAIPEI CITY (TW)

(21) Appl. No.: 16/510,271

(22) Filed: Jul. 12, 2019

Related U.S. Application Data
(60) Provisional application No. 62/785,561, filed on Dec. 27, 2018.

(51) Int. Cl. H01L 23/538; H01L 23/532

(52) U.S. Cl. CPC H01L 23/5384; H01L 23/5386; H01L 23/53295

(57) ABSTRACT

A semiconductor structure includes a substrate; a first conductive line and a second conductive line disposed over the substrate; a first dielectric layer disposed over the substrate and surrounding the first conductive line and the second conductive line; a first conductive via extending through the first dielectric layer and contacting the first conductive line; a third conductive line disposed over the first dielectric layer and contacting the first conductive via; and a second dielectric layer disposed over the first dielectric layer and surrounding the third conductive line, wherein the first conductive line and the second conductive line are overlaid by the third conductive line.

### PRIORITY CLAIM AND CROSS-REFERENCE

This application claims the priority benefit of U.S. provisional application Ser. No. 62/785,561 filed on Dec. 27, 2018. The entirety of the above-mentioned patent application is hereby incorporated by reference herein and made a part of this specification.

### TECHNICAL FIELD

The present disclosure relates to a semiconductor structure, and particularly relates to an interconnect structure in the semiconductor structure. Further, the present disclosure relates to a method of manufacturing the semiconductor structure comprising the interconnect structure.

### DISCUSSION OF THE BACKGROUND

Semiconductor devices are essential for many modern applications. With the advancement of electronic technology, semiconductor devices are becoming smaller in size while having greater functionality and greater amounts of integrated circuitry. Due to the miniaturized scale of semiconductor devices, various types and dimensions of semiconductor devices performing different functions are integrated and packaged into a single module. Furthermore, numerous manufacturing operations are implemented for integration of various types of semiconductor devices.

However, the manufacturing and integration of semiconductor devices involve many complicated steps and operations. Integration of semiconductor devices in low-profile and high-density modules becomes increasingly complicated. An increase in complexity of manufacturing and integration of the semiconductor devices may cause deficiencies such as short circuit, poor electrical interconnection, delamination of components, etc.

Accordingly, there is a continuous need to improve the structure and the manufacturing of semiconductor devices.

This Discussion of the Background section is provided for background information only. The statements in this Discussion of the Background are not an admission that the subject matter disclosed in this Discussion of the Background section constitutes prior art to the present is disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure comprising a substrate; a first conductive line and a second conductive line disposed over the substrate; a first dielectric layer disposed over the substrate and surrounding the first conductive line and the second conductive line; a first conductive via extending through the first dielectric layer and contacting the first conductive line; a third conductive line disposed over the first dielectric layer and contacting the first conductive via; and a second dielectric layer disposed over the first dielectric layer and surrounding the third conductive line, wherein the first conductive line and the second conductive line are overlaid by the third conductive line.

In some embodiments, a width of the third conductive line is substantially greater than a width of the first conductive line or a width of the second conductive line.

In some embodiments, a width of the third conductive line is at least two times a width of the first conductive line.

In some embodiments, the first conductive line and the second conductive line extend in parallel to each other.

In some embodiments, the semiconductor structure further comprises a fourth conductive line disposed between the first conductive line and the second conductive line.

In some embodiments, the fourth conductive line is overlaid by the third conductive line.

In some embodiments, the fourth conductive line is electrically isolated from the first conductive line, the second conductive line and the third conductive line.

In some embodiments, the semiconductor structure further comprises a second conductive via extending between and contacting the second conductive line and the third conductive line.

In some embodiments, the first conductive line is electrically connected to the second conductive line through the first conductive via, the second conductive via and the third conductive line.

In some embodiments, the first conductive via is aligned with the second conductive via.

In some embodiments, a shortest distance between an edge of the third conductive line and an edge of the second conductive via is substantially greater than about 230 nm.

In some embodiments, the third conductive line extends along the first conductive line or the second conductive line, and has a length substantially greater than a distance between the first conductive line and the second conductive line.

In some embodiments, a shortest distance between an edge of the third conductive line and an edge of the first conductive via is substantially is greater than about 230 nm.

In some embodiments, the first conductive line and the second conductive line are physically isolated from each other.

In some embodiments, the first conductive via is disposed above a portion of the first dielectric layer and is shifted away from the first conductive line towards the second conductive line.

Another aspect of the present disclosure provides a method of manufacturing a semiconductor structure comprising a substrate; a plurality of first conductive lines disposed over the substrate; a first dielectric layer disposed over the substrate and surrounding the plurality of first conductive lines; a plurality of conductive vias extending through the first dielectric layer and respectively in contact with the plurality of first conductive lines; a plurality of second conductive lines disposed over the first dielectric layer and in contact with the plurality of first conductive vias; and a second dielectric layer disposed over the first dielectric layer and surrounding the plurality of second conductive lines, wherein one of the plurality of second conductive lines is disposed over and extends along at least two of the plurality of first conductive lines.

In some embodiments, a distance between an adjacent pair of the plurality of second conductive lines is substantially greater than a width of one of the plurality of first conductive lines.

In some embodiments, two of the plurality of first conductive lines are coupled with each other.

In some embodiments, each of the plurality of second conductive lines has a rectangular shape.

In some embodiments, the plurality of second conductive lines extend in parallel to each other.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 is a schematic top view of a semiconductor structure in accordance with some embodiments of the present disclosure.

FIG. 2 is a schematic cross-sectional view of the semiconductor structure along a line A-A′ of FIG. 1 in accordance with some embodiments of the present disclosure.

FIG. 3 is a schematic cross-sectional view of the semiconductor is structure along a line B-B′ of FIG. 1 in accordance with some embodiments of the present disclosure.

FIG. 4 is a flowchart of a method of manufacturing a semiconductor structure in accordance with some embodiments of the present disclosure.

FIGS. 5 to 15 are schematic views of manufacturing the semiconductor structure by the method of FIG. 4 in accordance with some embodiments of the present disclosure.

### DETAILED DESCRIPTION

The following description of the disclosure accompanies drawings, which are incorporated in and constitute a part of this specification, and illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, is detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

A semiconductor structure is manufactured by several processes. During fabrication of the semiconductor structure, several dielectric layers are disposed over a substrate, several conductive traces and electrical components are disposed over one of the dielectric layers, and several vias extend through at least one of the dielectric layers to electrically connect the conductive traces and the electrical components to form circuitries. However, overall sizes of semiconductor structures continue to become smaller and smaller. As such, conductive traces may easily bridge with each other, which leads to failure of electrical connection and short circuit. As a result, reliability of the semiconductor structure is adversely affected.

In the present disclosure, a semiconductor structure is disclosed. The semiconductor structure includes a substrate; a first dielectric layer disposed over to the substrate; a first conductive line and a second conductive line disposed over the first dielectric layer; a second dielectric layer disposed over the first dielectric layer and surrounding the first conductive line and the second conductive line; a first conductive via extending through the second dielectric layer and contacting the first conductive line; and a third conductive line disposed over the second is dielectric layer and contacting the first conductive via, wherein the first conductive line and the second conductive line are overlaid by the third conductive line.

The third conductive line has a relatively large size and thus is disposed above the first conductive line and the second conductive line. As such, the third conductive line does not bridge with other conductive lines disposed between the first conductive line and the second conductive line. Therefore, short circuit between conductive lines can be reduced or prevented.

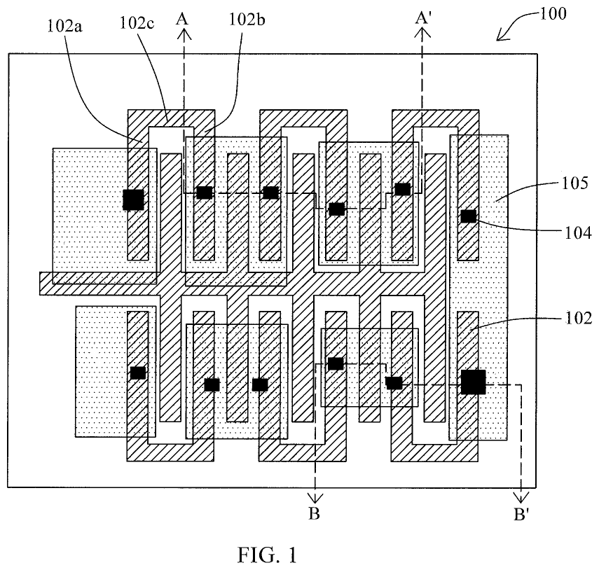

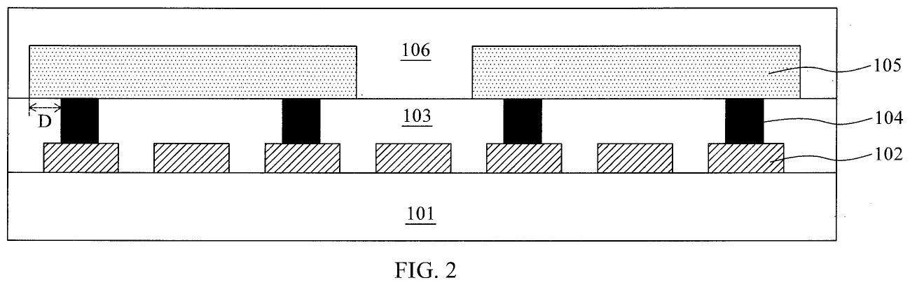

FIG. 1 is a schematic top view of a semiconductor structure 100 in accordance with some embodiments of the present disclosure. FIG. 2 is a schematic cross-sectional view of the semiconductor structure 100 along a line

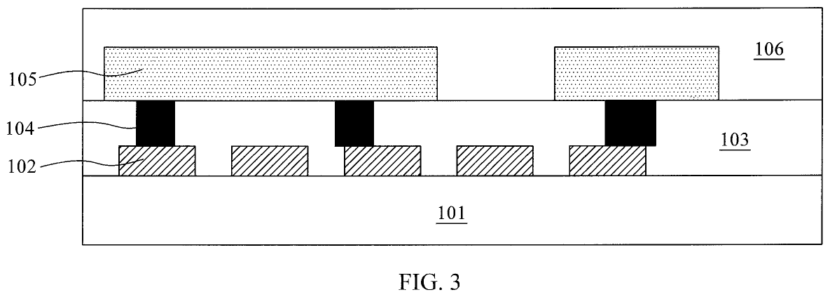

A-A′ of FIG. 1, and FIG. 3 is a schematic cross-sectional view of the semiconductor structure along a line B-B′ of FIG. 1.

In some embodiments, the semiconductor structure 100 is a semiconductor package or a part of the semiconductor package. In some embodiments, the semiconductor structure 100 is a die or a part of the die. In some embodiments, the semiconductor structure 100 includes a substrate 101, several first conductive lines 102, a first dielectric layer 103, several conductive vias 104, several second conductive lines 105 and a second dielectric layer 106.

In some embodiments, the substrate 101 is a semiconductive substrate. In some embodiments, the substrate 101 includes semiconductive material such as silicon, germanium, gallium, arsenic, and combinations thereof. In some embodiments, the substrate 101 includes material such as ceramic, glass or the like. In some embodiments, the substrate 101 is fabricated with a predetermined functional circuit thereon. In some embodiments, the substrate 101 includes several electrical components such as transistors, diodes, etc. disposed over the substrate 101.

In some embodiments, an interlayer dielectric (ILD) is disposed over the substrate 101. In some embodiments, the ILD 102 includes dielectric material such as silicon oxide, borophosphosilicate glass (BPSG), phosphosilicate glass (PSG) or the like. In some embodiments, a gate structure is disposed in the ILD. In some embodiments, several semiconductor devices such as transistors or the like are disposed in the ILD.

In some embodiments, the first conductive lines 102 are disposed over the substrate 101. In some embodiments, the first conductive lines 102 extend over a surface of the substrate 101. In some embodiments, the first conductive lines 102 are substantially coplanar with each other. In some embodiments, the first conductive lines 102 extend in parallel to each other. In some embodiments, the first conductive lines 102 are disposed over the ILD. In some embodiments, the first conductive lines 102 are physically isolated from each other. In some embodiments, two or more of the first conductive lines 102 are coupled with each other.

In some embodiments, the first conductive line 102 has a width and a length substantially greater than the width. In some embodiments, an aspect ratio of the length to the width of the first conductive line 102 is substantially greater than 5:1. In some embodiments, the aspect ratio of the first conductive line 102 is between about 3:1 and about 20:1.

In some embodiments, the first conductive line 102 is in a U shape. In some embodiments, the first conductive line 102 includes a first elongated portion 102a, a second elongated portion 102b and a third elongated portion 102c is coupled to an end of the first elongated portion 102a and an end of the second elongated portion 102b. In some embodiments, the first elongated portion 102b extends substantially in parallel to the second elongated portion 102c.

In some embodiments, the first elongated portion 102a is spaced apart from the second elongated portion 102b. In some embodiments, one of the first conductive lines 102 is disposed between the first elongated portion 102a and the second elongated portion 102b and is electrically isolated from the first elongated portion 102a and the second elongated portion 102b.

In some embodiments, the first dielectric layer 103 is disposed over the substrate 101 and surrounding the first conductive lines 102. In some embodiments, the first dielectric layer 103 includes several layers of dielectric material stacked over each other. In some embodiments, the first dielectric layer 103 is an intermetal dielectric (IMD) surrounding several conductive structures. In some embodiments, the first dielectric layer 103 includes dielectric material such as silicon oxide, undoped silicate glass (USG), fluorinated silicate glass (FSG) or the like.

In some embodiments, the conductive vias 104 extend through the first dielectric layer 103 and are respectively and correspondingly in contact with the first conductive lines 102. In some embodiments, the conductive vias 104 are respectively disposed above the first conductive lines 102. In some embodiments, the conductive vias 104 are surrounded by the first dielectric layer 103.

In some embodiments, the conductive vias 104 extend substantially orthogonal to the first conductive lines 102. In some embodiments, the conductive vias 104 are electrically isolated from other adjacent first conductive lines 102. In some embodiments, one of the conductive vias 104 is aligned with is another one of the conductive vias 104. In some embodiments, the conductive via 104 includes copper, gold, silver, aluminum or the like.

In some embodiments, the second conductive lines 105 are disposed over the first dielectric layer 103 and contact the conductive vias 104. In some embodiments, the second conductive lines 105 extend over a surface of the first dielectric layer 103. In some embodiments, the second conductive lines 105 extend in parallel to each other. In some embodiments, the second conductive lines 105 are substantially coplanar with each other. In some embodiments, the second conductive line 105 is disposed above the conductive via 104. In some embodiments, the first conductive line 102 is electrically connected to the second conductive line 105 through the conductive via 104. In some embodiments, the conductive via 104 extends between the first conductive line 102 and the second conductive line 105.

In some embodiments, at least two of the first conductive lines 102 are overlaid by one of the second conductive lines 105. For example, as shown in FIG. 2, three of the first conductive lines 102 are overlaid by one of the second conductive lines 105. In some embodiments, two of the first conductive lines 102 are electrically connected through two corresponding conductive vias 104 and one of the second conductive lines 105.

In some embodiments, the second conductive line 105 extends along one of the first conductive lines 102. In some embodiments, the second conductive line 105 is disposed above and extends along at least two of the first conductive lines 102. In some embodiments, the second conductive line 105 extends along the length of the first conductive line 102. In some embodiments, the second conductive line 105 has a width and a length substantially greater than is the width. In some embodiments, the length of the second conductive line 105 is substantially greater than a distance between two adjacent first conductive lines 102.

In some embodiments, the length of the second conductive line 105 is at least two times the width of the second conductive line 105. In some embodiments, the width of the second conductive line 105 is substantially greater than the width of the first conductive line 102. In some embodiments, the width of the second conductive line 105 is at least two times the width of the first conductive line 102.

In some embodiments, an aspect ratio of the length to the width of the second conductive line 105 is substantially greater than 2:1 and less than 10:1. In some embodiments, the aspect ratio of the second conductive line 105 is between about 1:1 and about 8:1. In some embodiments, the width of the second conductive line 105 is at least two times the width of the first conductive line 102. In some embodiments, the second conductive line 105 has a rectangular shape.

In some embodiments, a shortest distance D between an edge of the second conductive line 105 and an edge of the conductive via 104 is substantially greater than about 200 nm. In some embodiments, the shortest distance D is substantially greater than 230 nm. In some embodiments, a distance between an adjacent pair of the second conductive lines 105 is substantially greater than the width of one of the first conductive lines 102.

In some embodiments, as shown in FIG. 3, the conductive via 104 is disposed above a portion of the first dielectric layer 103. In some embodiments, the conductive via 104 is shifted away from the corresponding one of the first conductive lines 102. In some embodiments, a central axis of the conductive via 104 is shifted away from a central axis of the corresponding one of the first conductive lines 102.

In some embodiments, the second dielectric layer 106 is disposed over the first dielectric layer 103 and surrounds the second conductive lines 105. In some embodiments, the second dielectric layer 106 includes several layers of dielectric material stacked over each other. In some embodiments, the second dielectric layer 106 is an intermetal dielectric (IMD) surrounding several conductive structures. In some embodiments, the second dielectric layer 106 includes dielectric material such as silicon oxide, undoped silicate glass (USG), fluorinated silicate glass (FSG) or the like. In some embodiments, the first dielectric layer 103 and the second dielectric layer 106 includes same or different dielectric materials.

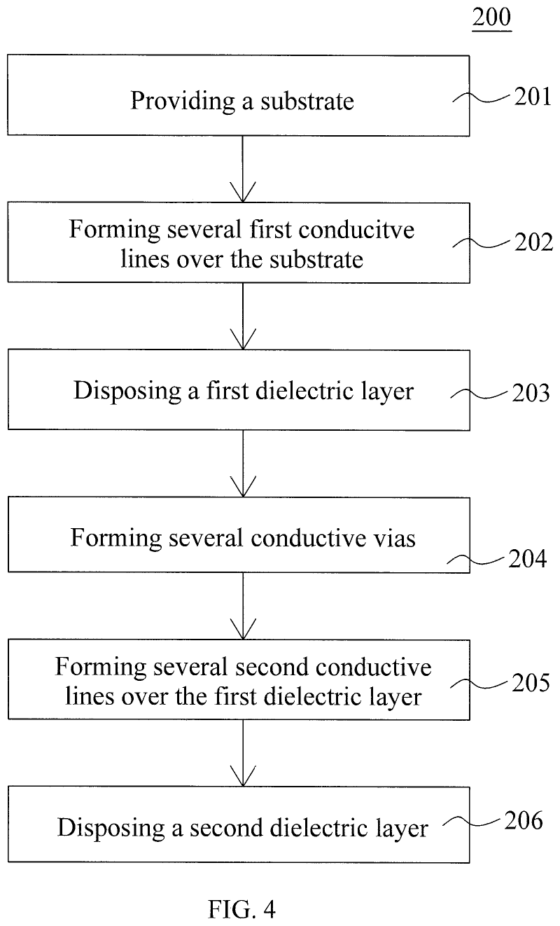

In the present disclosure, a method of manufacturing a semiconductor structure is also disclosed. In some embodiments, a semiconductor structure 100 can be formed by a method 200 as shown in FIG. 4. The method 200 includes a number of operations and the description and illustration are not deemed as a limitation to the sequence of the operations. The method 200 includes a number of steps (201, 202, 203, 204, 205 and 206).

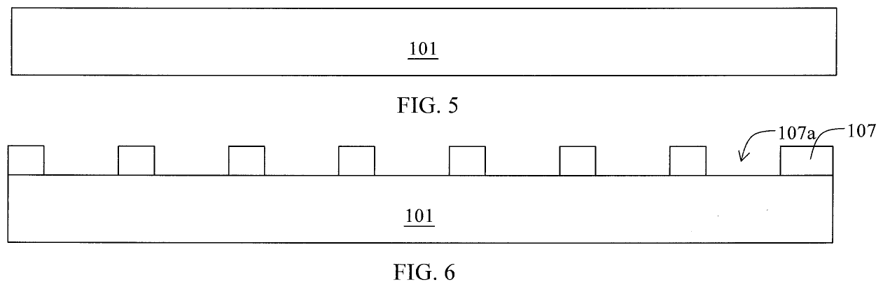

In step 201, a substrate 101 is provided as shown in FIG. 5. In some embodiments, the substrate 101 includes silicon or the like. In some embodiments, the substrate 101 has configurations similar to those described above or shown in FIGS. 1 to 3.

In some embodiments, an ILD is formed over the substrate. In some embodiments, the formation of the ILD includes disposing a dielectric material such as silicon oxide, BPSG or the like, and forming a semiconductor device such as transistor or the like in the dielectric material. In some embodiments, the is dielectric material is disposed by chemical vapor deposition (CVD) or any other suitable operations.

In some embodiments, a first photoresist 107 is disposed over the substrate 101 as shown in FIG. 6. In some embodiments, the first photoresist 107 is a light-sensitive material with chemical properties that depend on exposure to an electromagnetic radiation. The first photoresist 107 is sensitive to a predetermined electromagnetic radiation such as ultraviolet (UV) radiation, visible light or infrared (IR) radiation, such that the chemical properties of the first photoresist 107 are changed upon exposure to the predetermined electromagnetic radiation. In some embodiments, the first photoresist 107 is disposed over the substrate 101 by spin coating or any other suitable process. In some embodiments, the first photoresist 107 is a positive photoresist 702a, which is soluble in a predetermined developer after exposure to the predetermined electromagnetic radiation.

In some embodiments, after the disposing of the first photoresist 107, the first photoresist 107 is patterned by exposing some predetermined portions of the first photoresist 107 to the predetermined electromagnetic radiation through a mask, and removing those exposed portions. In some embodiments, several first openings 107a are formed after the patterning.

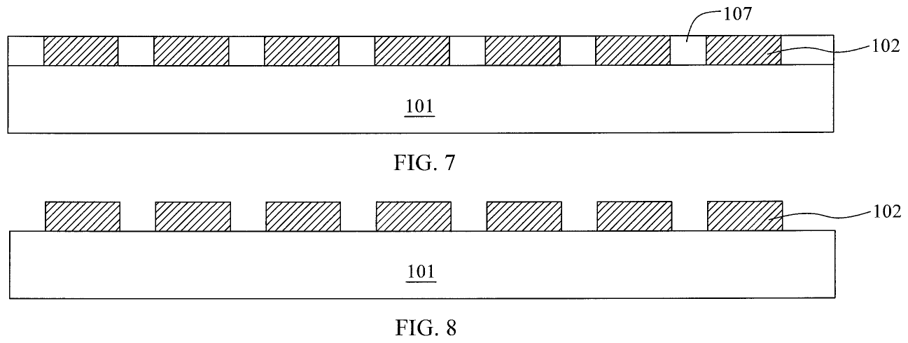

In step 202, several first conductive lines 102 are formed over the substrate 101 as shown in FIGS. 7 to 8. In some embodiments, the first conductive lines 102 are formed over the ILD. In some embodiments, the first conductive lines 102 are formed by disposing conductive material into the first openings 107a, as shown in FIG. 7. In some embodiments, the conductive material is disposed by sputtering, electroplating or any other suitable operations. In some embodiments, as shown in FIG. 8, the first photoresist 107 is removed is after the disposing of the conductive material. In some embodiments, the first conductive lines 102 have configurations similar to those described above or shown in FIGS. 1 to 3.

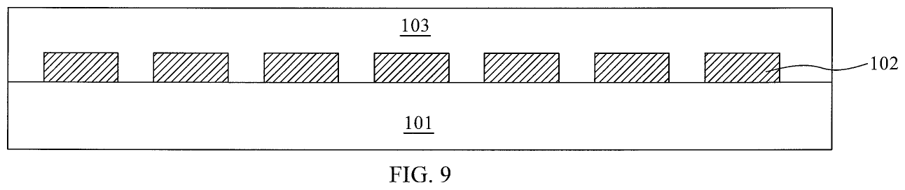

In step 203, a first dielectric layer 103 is disposed over the substrate 101 and the first conductive lines 102 as shown in FIG. 9. In some embodiments, the first conductive lines 102 are covered by the first dielectric layer 103. In some embodiments, the first dielectric layer 103 is formed by disposing a dielectric material such as silicon oxide or the like. In some embodiments, the dielectric material is disposed by CVD or any other suitable operations.

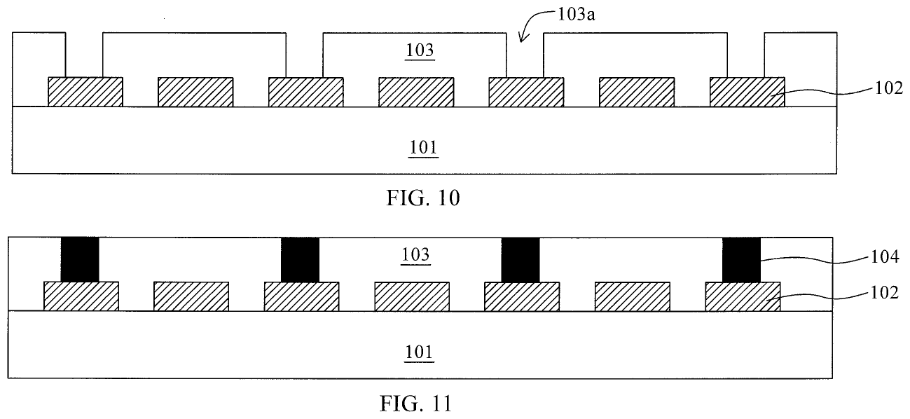

In step 204, several conductive vias 104 are formed as shown in FIGS. 10 to 11. In some embodiments, some portions of the first dielectric layer 2018-0339-US 103 are removed to form several second openings 103a as shown in FIG. 10. In some embodiments, the portions of the first dielectric layer 103 are removed by photolithography, etching or any other suitable operations. In some embodiments, the portions of the first dielectric layer 103 are disposed above corresponding first conductive lines 102.

In some embodiments, the conductive vias 104 are formed by disposing conductive material into the second openings 103a, as shown in FIG. 10. In some embodiments, the conductive material is disposed by sputtering, electroplating or any other suitable operations. In some embodiments, the first dielectric layer 103 and the conductive vias 104 have configurations similar to those described above or shown in FIGS. 1 to 3.

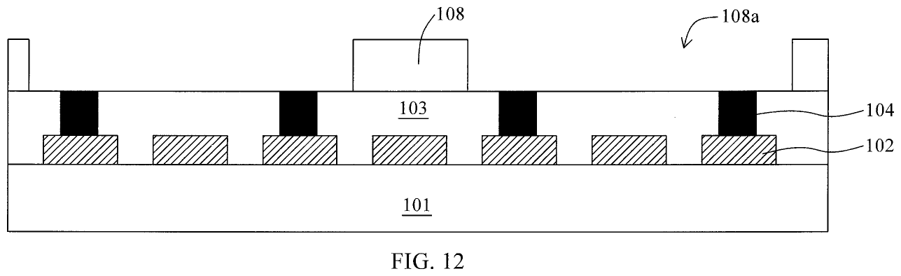

In some embodiments, a second photoresist 108 is disposed over the first dielectric layer 103 as shown in FIG. 12. In some embodiments, the second photoresist 108 has configurations similar to those of the first photoresist 107. In is some embodiments, after the disposing of the second photoresist 108, the second photoresist 108 is patterned by exposing some predetermined portions of the second photoresist 108 to the predetermined electromagnetic radiation through a mask, and removing the exposed portions.

In some embodiments, several third openings 108a are formed after the patterning. In some embodiments, at least two of the first conductive lines 102 are overlaid by one of the third openings 108a. In some embodiments, the third opening 108a has a width and a length substantially greater than the width. In some embodiments, the width of the third opening 108a is at least two times the width of third opening 108a.

In some embodiments, an aspect ratio of the length to the width of the third opening 108a is substantially greater than 2:1 and less than 10:1. In some embodiments, the aspect ratio of the third opening 108a is between about 1:1 and about 8:1. In some embodiments, the width of the third opening 108a is at least two times the width of the first conductive line 102. In some embodiments, the third opening 108a has a rectangular shape.

In some embodiments, the third opening 108a extends along one of the first conductive lines 102 or one of the first openings 107a. In some embodiments, the third opening 108a extends along at least two of the first openings 107a.

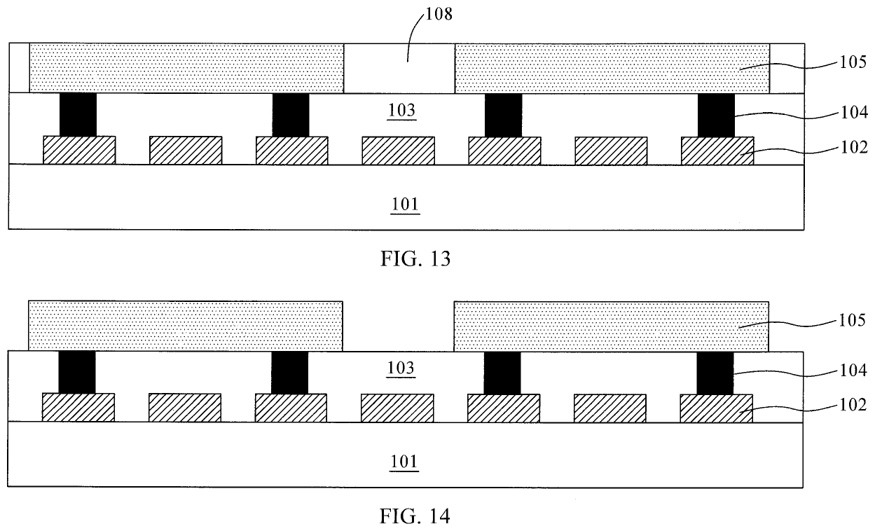

In step 205, several second conductive lines 105 are formed over the first dielectric layer 103 as shown in FIGS. 13 to 14. In some embodiments, the second conductive lines 105 are formed over the first conductive lines 102 and the conductive vias 104.

In some embodiments, the second conductive lines 105 are formed by disposing conductive material into the third openings 108a, as shown in FIG. 13. In some embodiments, the conductive material is disposed by sputtering, electroplating or any other suitable operations. In some embodiments as shown in FIG. 14, the second photoresist 108 is removed after the disposing of the conductive material. In some embodiments, the second conductive lines 105 have configurations similar to those described above or shown in FIGS. 1 to 3.

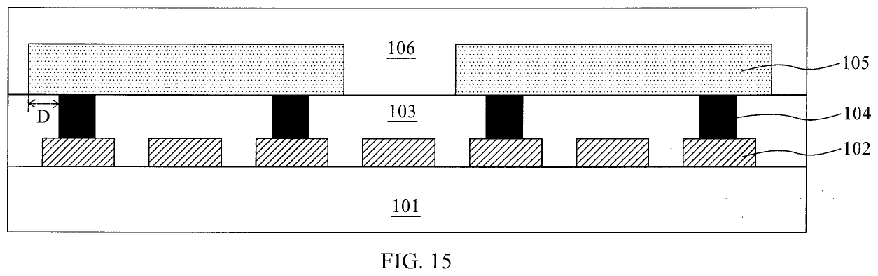

In step 206, a second dielectric layer 106 is disposed over the first dielectric layer 103 and the second conductive lines 105 as shown in FIG. 15. In some embodiments, the second conductive lines 105 are covered by the second dielectric layer 106. In some embodiments, the second dielectric layer 106 is formed by disposing a dielectric material such as silicon oxide or the like. In some embodiments, the dielectric material is disposed by CVD or any other suitable operations.

Although the present disclosure and its advantages have been described in detail, it should be understood that various changes, substitutions and alterations can be made herein without departing from the spirit and scope of the disclosure as defined by the appended claims. For example, many of the processes discussed above can be implemented through different methods, replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of is matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor structure, comprising:
a substrate;
a first conductive line and a second conductive line disposed over the substrate;
a first dielectric layer disposed over the substrate and surrounding the first conductive line and the second conductive line;
a first conductive via extending through the first dielectric layer and contacting the first conductive line;
a third conductive line disposed over the first dielectric layer and contacting the first conductive via; and
a second dielectric layer disposed over the first dielectric layer and surrounding the third conductive line,
wherein the first conductive line and the second conductive line are is overlaid by the third conductive line.

2. The semiconductor structure of claim 1, wherein a width of the third conductive line is substantially greater than a width of the first conductive line or a width of the second conductive line.

3. The semiconductor structure of claim 1, wherein a width of the third conductive line is at least two times a width of the first conductive line.

4. The semiconductor structure of claim 1, wherein the first conductive line and the second conductive line extend in parallel to each other.

5. The semiconductor structure of claim 1, further comprising a fourth conductive line disposed between the first conductive line and the second conductive line.

6. The semiconductor structure of claim 5, wherein the fourth conductive line is overlaid by the third conductive line.

7. The semiconductor structure of claim 5, wherein the fourth conductive line is electrically isolated from the first conductive line, the second conductive line and the third conductive line.

8. The semiconductor structure of claim 1, further comprising a second conductive via extending between and contacting the second conductive line and the third conductive line.

9. The semiconductor structure of claim 8, wherein the first conductive line is electrically connected to the second conductive line through the first conductive via, the second conductive via and the third conductive line.

10. The semiconductor structure of claim 8, wherein the first conductive via is aligned with the second conductive via.

11. The semiconductor structure of claim 8, wherein a shortest distance between an edge of the third conductive line and an edge of the second conductive via is substantially greater than about 230 nm.

12. The semiconductor structure of claim 1, wherein the third conductive line extends along the first conductive line or the second conductive line, and the third conductive line has a length substantially greater than a distance between the first conductive line and the second conductive line.

13. The semiconductor structure of claim 1, wherein a shortest distance between an edge of the third conductive line and an edge of the first conductive via is substantially greater than about 230 mn.

14. The semiconductor structure of claim 1, wherein the first conductive line and the second conductive line are physically isolated from each other.

15. The semiconductor structure of claim 1, wherein the first conductive via is disposed above a portion of the first dielectric layer and is shifted away from the first conductive line towards the second conductive line.

16. A semiconductor structure, comprising:
a substrate;
a plurality of first conductive lines disposed over the substrate;
a first dielectric layer disposed over the substrate and surrounding the plurality of first conductive lines;
a plurality of conductive vias extending through the first dielectric is layer and respectively contacting the plurality of first conductive lines;
a plurality of second conductive lines disposed over the first dielectric layer and contacting the plurality of first conductive vias; and
a second dielectric layer disposed over the first dielectric layer and surrounding the plurality of second conductive lines,
wherein one of the plurality of second conductive lines is disposed over and extends along at least two of the plurality of first conductive lines.

17. The semiconductor structure of claim 16, wherein a distance between an adjacent pair of the plurality of second conductive lines is substantially greater than a width of one of the plurality of first conductive lines.

18. The semiconductor structure of claim 16, wherein two of the plurality of first conductive lines are coupled with each other.

19. The semiconductor structure of claim 16, wherein each of the plurality of second conductive lines has a rectangular shape.

20. The semiconductor structure of claim 16, wherein the plurality of second conductive lines extend in parallel to each other.
